(19) United States
(12) Patent Application Publication
(10) Pub. No.: US 2022/0413053 A1
(43) Pub. Date: Dec. 29, 2022

(54) INFORMATION PROVIDING SYSTEM, SERVER, AND INFORMATION PROVIDING METHOD

(71) Applicant: HONDA MOTOR CO., LTD., Tokyo (JP)

(72) Inventors: Koichi TSUNO, Wako-shi (JP); Yasuhiro NAKADA, Wako-shi (JP); Takumi SHIIYAMA, Wako-shi (JP)

(21) Appl. No.: 17/899,852

(22) Filed: Aug. 31, 2022

Related U.S. Application Data
(63) Continuation of application No. PCT/JP2021/007866, filed on Mar. 2, 2021.

(30) Foreign Application Priority Data
Mar. 27, 2020 (JP) 2020-057887

(51) Int. Cl. G01R 31/367; H02J 7/00; G01R 31/392

(52) U.S. Cl. CPC G01R 31/367; H02J 7/0047; G01R 31/392; G06Q 50/06

(57) ABSTRACT

An information providing system in which a plurality of information collection devices, a server, and a plurality of information reception devices are connected by a network, each of the plurality of information collection devices comprises: a rechargeable battery configured to supply power to drive the information collection device; a monitoring circuit configured to monitor a state of the battery; a sensor configured to detect a state of an environment where the plurality of information collection devices are installed; a memory configured to store first data indicating a history of the state of the battery monitored by the monitoring circuit and second data indicating a state of the environment detected by the sensor; and a transmission unit configured to transmit the first data and the second data stored in the memory via the network based on a request from the server.

### CROSS-REFERENCE TO RELATED APPLICATION(S)

This application is a continuation of International Patent Application No. PCT/JP2021/007866 filed on Mar. 2, 2021, which claims priority to and the benefit of Japanese Patent Application No. 2020-057887 filed on Mar. 27, 2020, the entire disclosures of which are incorporated herein by reference.

### BACKGROUND OF THE INVENTION

### Field of the Invention

The present invention relates to an information providing system, a server, and an information providing method, and particularly relates to, for example, an information providing system, a server, and an information providing method based on history data of a state of a reusable battery used as a power source of various devices.

### Description of the Related Art

In the related art, a chargeable secondary battery such as a lithium ion battery is used as a power storage device in a vehicle such as an electrical vehicle or a hybrid vehicle.

A sensor monitoring a deterioration state and a use environment of the secondary battery is contained in the secondary battery. Various physical quantities detected by the sensor are acquired as detection data, and SOH and SOC of the secondary battery can be estimated based on the acquired data. Appropriate maintenance management is performed by obtaining a present state of the secondary battery based on the estimation and notifying a user of the present state.

Therefore, in the related art, a system that appropriately manages such a secondary battery has been proposed. For example, International Publication No. 2019/235645 A proposes a configuration capable of remotely monitoring a state of a secondary battery of an electronic device.

The above-described example of the related art deals with state management of a new secondary battery. For example, a secondary battery mounted in a vehicle is provided in accordance with high standards and regulations for safe operation of the vehicle. When the standards are not satisfied, the secondary battery cannot be mounted in the vehicle for use. For example, when a chargeable capacity of the secondary battery becomes equal to or less than a predetermined amount, it is necessary to replace the secondary battery with a new secondary battery. However, even if the secondary battery does not satisfy the standards for use in the vehicle, performance of the secondary battery may still be maintained sufficiently highly, and the secondary battery can be sufficiently used as long as the secondary battery is not used for a vehicle.

Actually, attempts have been made to reuse such secondary batteries. A secondary battery reused in this way is often referred to as a reusable battery. Such a reusable battery has an advantage that the reusable battery can be used relatively inexpensively and is expected to be used as a promising power source in fields in which high reliability is not required. For example, the present invention can be applied to an emergency stationary storage battery, an agricultural tool, a power source in a residence in a mountainous area or an island area, and the like.

Appropriate maintenance and management are also necessary for safe use of such reusable batteries. However, reusable batteries have been used in various different environments and use conditions. Thus, there is a problem that the degree of deterioration cannot be accurately predicted even if a deterioration model of the related art for a new secondary battery is applied.

The present invention has been made in view of the above-described example of the related art and provides an information providing technology capable of constructing an accurate deterioration model based on, for example, history data acquired from a reusable battery and providing the accurate deterioration model so that a user can use the battery.

### SUMMARY OF THE INVENTION

According to one aspect of the present invention, there is provided an information providing system in which a plurality of information collection devices, a server, and a plurality of information reception devices are connected by a network,

each of the plurality of information collection devices comprising:

a rechargeable battery configured to supply power to drive the information collection device;

a monitoring circuit configured to monitor a state of the battery;

a sensor configured to detect a state of an environment where the plurality of information collection devices are installed;

a memory configured to store first data indicating a history of the state of the battery monitored by the monitoring circuit and second data indicating a state of the environment detected by the sensor; and

a transmission unit configured to transmit the first data and the second data stored in the memory via the network based on a request from the server,

the server comprising:

a request unit configured to issue a data transmission request to each of the plurality of information collection devices via the network;

a collection unit configured to collect the first data and the second data from each of the plurality of information collection devices via the network;

a database configured to store the first data and the second data collected by the collection unit;

a construction unit configured to construct a power demand model in which the battery is used based on the first data and the second data stored in the database; and

a providing unit configured to provide at least one of the first data and the second data stored in the database, and the power demand model to the plurality of information reception devices via the network for a fee, and

the plurality of information reception devices comprising:

a reception unit configured to receive at least one of the first data, the second data, and the power demand model provided from the server.

According to another aspect of the present invention, there is provided a server that connects a plurality of information collection devices driven with power supplied from a rechargeable battery to a plurality of information reception devices via a network, the server comprising:

a request unit configured to issue a data transmission request to each of the plurality of information collection devices via the network;

a collection unit configured to collect, via the network, first data indicating a history of a state of the battery transmitted from each of the plurality of information collection devices and second data indicating a state of an environment where the plurality of information collection devices are installed in response to the transmission request;

a database configured to store the first data and the second data collected by the collection unit;

a construction unit configured to construct a power demand model in which the battery is used based on the first data and the second data stored in the database; and

a providing unit configured to provide at least one of the first data and the second data stored in the database, and the power demand model to the plurality of information reception devices via the network for a fee.

According to still another aspect of the present invention, there is provided an information providing method in a server that connects a plurality of information collection devices driven by power supplied from a rechargeable battery and a plurality of information reception devices via a network, the information providing method comprising:

issuing a data transmission request to each of the plurality of information collection devices via the network;

collecting, via the network, first data indicating a history of a state of the battery transmitted from each of the plurality of information collection devices and second data indicating a state of an environment where the plurality of information collection devices are installed in response to the transmission request;

storing the collected first data and second data in a database;

constructing a power demand model in which the battery is used based on the first data and the second data stored in the database; and

providing at least one of the first data and the second data stored in the database, and the power demand model to the plurality of information reception devices via the network for a fee.

According to the present invention, it is possible to construct an accurate deterioration model based on history data acquired from a rechargeable battery and provide the accurate deterioration model so that a user can use the battery.

Further features of the present invention will become apparent from the following description of exemplary embodiments with reference to the attached drawings.

### BRIEF DESCRIPTION OF THE DRAWINGS

FIG. 1 is a block diagram illustrating an overview of a configuration of an information providing system which is a representative embodiment of the present invention;

FIG. 2 is a block diagram illustrating a configuration of a reusable battery;

FIG. 3 is a block diagram illustrating a configuration of a server serving as an information distribution device or an information processing device;

FIG. 4 is a diagram illustrating a schematic configuration of an information reception device in a PC form;

FIG. 5A is a flowchart illustrating a data collection process performed by the reusable battery;

FIG. 5B is a diagram illustrating a configuration of a transmission format of data transmitted from the reusable battery;

FIG. 6 is a flowchart illustrating details of the data collection process;

FIG. 7 is a flowchart illustrating the deterioration model correction process;

FIG. 8 is a diagram illustrating deterioration prediction by the pre-correction deterioration model and the post-correction deterioration model; and

FIG. 9 is a flowchart illustrating a selling process executed by the server.

### DESCRIPTION OF THE EMBODIMENTS

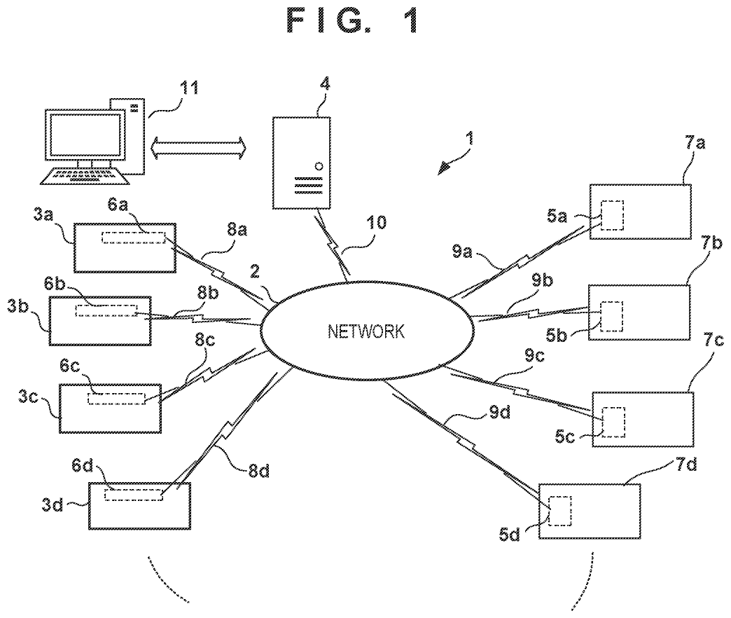

Hereinafter, preferred embodiments of the present invention will be described in more detail with reference to the accompanying drawings.

<System Configuration (See FIG. 1)>

FIG. 1 is a block diagram illustrating an overview of a configuration of an information providing system 1 which is a representative embodiment of the present invention.

The information providing system 1 illustrated in FIG. 1 includes a plurality of information collection devices 3a to 3d, a plurality of information reception devices 7a to 7d, and a server (an information distribution device) 4 connected to be communicable via a network 2. Although the four information collection devices 3a to 3d and the four information reception devices 7a to 7d are exemplified in FIG. 1, more devices may be included. A terminal device 11 performing system monitoring, model construction for optimum information provision, and information distribution is connected to the server 4. In FIG. 1, one terminal device 11 is connected, but the present invention is not limited to this number. A plurality of terminal devices may be provided according to needs.

Each of the plurality of information collection devices 3a to 3d operates with power supplied by contained reusable batteries 6a to 6d. Types of the plurality of information collection devices 3a to 3d are, for example, stationary power storage devices of power generators (solar power generation, wind power generation, and the like) installed at different locations or operated at different locations, agricultural work machines (lawn mowers, cultivators, etc.), disaster-response storage batteries, residential storage batteries, weather observation equipment, and the like.

Each of the reusable batteries 6a to 6d has a communication function and can establish communication links 8a to 8d with the network 2 to perform bidirectional communication with a communication partner. This communication function may be wired communication or wireless communication in conformity with a specific protocol. In this case, the wireless communication may be not only wireless communication via a ground network but also satellite communication via a communication satellite.

The reusable battery is a rechargeable secondary battery used as a power storage device of a vehicle such as an electrical vehicle or a hybrid vehicle, and is a rechargeable secondary battery that is not suitable for a vehicle because its chargeable capacity is equal to or less than a predetermined amount, but can be reused for other purposes. Specifically, a lithium ion battery is exemplified as a typical example. The vehicle may be a two-wheeled vehicle or a four-wheeled vehicle, and the secondary battery mounted in the vehicle may be of a cartridge type that is easily detachably mounted, of a type that is fixedly attached to the vehicle, or the like, regardless of a mounting method.

On the other hand, the plurality of information reception devices 7a to 7d are information processing devices in the form of a personal computer, a general-purpose computer, a tablet terminal, a smartphone, or the like, and can establish communication links 9a to 9d with the network 2 and perform bidirectional communication with a communication partner. This communication function may be wired communication or wireless communication in conformity with a specific protocol. Application programs 5a to 5d are installed in these information processing devices, and information collected by the plurality of information collection devices 3a to 3d can be received.

The plurality of information reception devices 7a to 7d are introduced into a weather company, an agricultural manager, a local developer, a local public organization, various manufacturers, a trading company, or the like that uses information collected by the plurality of information collection devices 3a to 3d. In addition, a user of a reusable battery who operates the information collection device using the reusable battery may introduce and use the information reception device for operation management of the reusable battery.

The information received by the application programs 5a to 5d is received via the server 4 connected to the network 2, instead of directly receiving the information collected by the plurality of information collection devices 3a to 3d. A communication link 10 is established between the network 2 and the server 4.

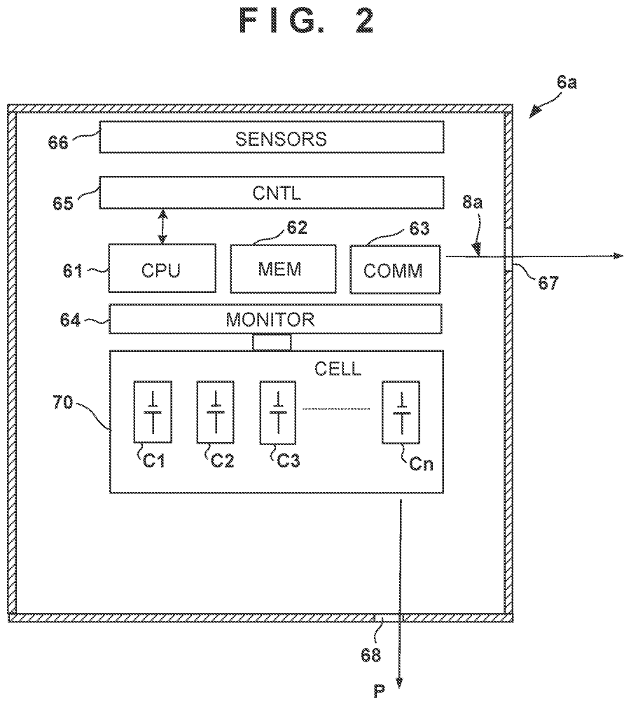

The server 4 connected to the network 2 receives information collected by the plurality of information collection devices 3a to 3d via the network 2, stores the received information, and further processes the received information into a format receivable by the plurality of information reception devices 7a to 7d. The collected information and the processed information are stored and accumulated in a database included in the server 4. The processed information is provided to the plurality of information reception devices 7a to 7d for a fee. Further, the server 4 and the terminal device 11 cooperate to reconstruct a deterioration model for predicting the SOH of each reusable battery based on the information acquired from the reusable battery. This reconstruction will be described below.

<Configuration of Reusable Battery (See FIG. 2)>

FIG. 2 is a block diagram illustrating a configuration of a reusable battery. The reusable batteries 6a to 6d have different sizes, providable power, estimated remaining life spans of the reusable batteries, and the like, but have a common basic configuration. Here, a configuration of the reusable battery 6a will be described here. Here, n cells C1, C2, Cn made of a lithium (Li) ion battery are contained as the battery cell 70. Power P provided from the battery cell 70 is supplied to the information collection device containing an output terminal 68 via the output terminal 68.

In addition to the lithium (Li) ion battery, a sodium ion secondary battery, a potassium ion secondary battery, or the like may be adopted as a cell of the battery cell 70.

As illustrated in FIG. 2, a discharge voltage, a power density, a cell temperature, an acceleration, and the like of the battery cell 70 are monitored by a monitoring circuit (MONITOR) 64. On the other hand, a sensor group (SENSORS) 66 such as a GPS sensor for specifying an installation location of the reusable battery 6a and a weather sensor for measuring an environmental state such as a temperature, an atmospheric pressure, a sunshine time, and humidity of the installation location is provided. An operation of the sensor group 66 is controlled by a sensor controller (CNTL) 65, and various measured physical quantities are transmitted to the CPU 61.

The CPU 61 adds an observation time to various physical quantity data measured by the sensor group 66 using an internal timer and stores the data in the memory 62. Similarly, the CPU 61 adds information acquisition time to monitoring information of the battery cell 70 monitored by the monitoring circuit 64 using the internal timer and stores the information in the memory 62.

The memory 62 includes a ROM that stores a control program operating the CPU 61, a RAM that is used as a working area where the control program is executed, an EEPROM capable of holding data even without power supply, and an SSD. Therefore, the data measured by the sensor group 66 and the monitoring information acquired by the monitoring circuit 64 are stored in the EEPROM or the SSD.

The reusable battery 6a establishes the communication link 8a with an external device such as the server 4 as described in FIG. 1 via the network 2 and includes a communication unit (COMM) 63 that transmits and receives data. The communication unit (COMM) 63 delivers the data stored in the memory 62 to the server 4 from an output terminal 67 in accordance with a method as will be described below. The communication unit (COMM) 63 may adopt a wireless communication system, a wired communication system, or a satellite communication system depending on the installation location. In any case, the communication unit (COMM) 63 managed and controlled by the CPU 61 can deliver the data stored in the memory 62 to the server 4. Here, when the communication unit (COMM) 63 adopts a wireless communication scheme, an antenna is connected to the output terminal 67. When a wired communication scheme is adopted, a coaxial cable, an optical cable, or the like is connected to the output terminal 67.

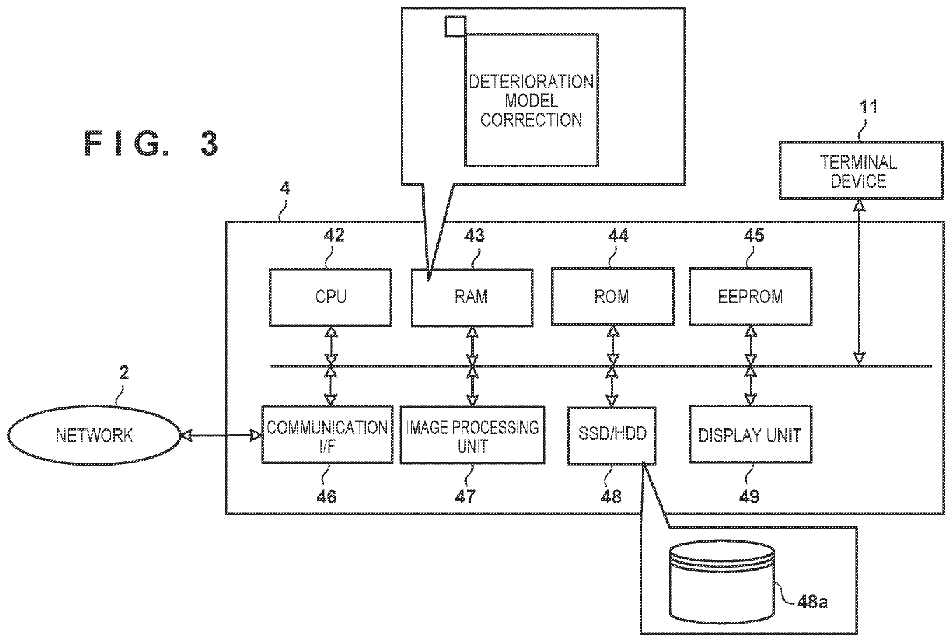

Since the battery cell 70 can be recharged, a charging device can be connected to the reusable battery and charging is performed by the charging device. The form of the charging device differs depending on a type of information collection device. For example, when the information collection device is a power generator (solar power generation, wind power generation, or the like), the power generator can serve as a charging device. If the information collection device is an agricultural work machine (lawn mowers, cultivators, etc.), a power generator driven by the power generator can serve as a charging device. In the case of a residential storage battery, a form of a charging device driven with power of AC 100 V to 240 V is adopted. In the case of a weather observation device installed on the sea, a form of a charging device driven by a power generator that generates power with wave energy or the like is adopted.

<Configuration of Server (See FIG. 3)>

FIG. 3 is a block diagram illustrating a configuration of a server serving as an information distribution device or an information processing device.

The server 4 is an information processing device that has a high-performance CPU, a large-capacity storage device, and a communication function. As illustrated in FIG. 3, the server 4 includes a CPU 42, a RAM 43, a ROM 44, an EEPROM 45 which is a nonvolatile memory, a communication interface (I/F) 46, an image processing unit 47, an SSD/HDD 48 which is a mass storage device, and a display unit 49. The terminal device 11 that operates the server 4 is connected. The terminal device 41 includes an MPU, a memory, a touch panel, a keyboard, an LED lamp, and an LCD and is operated by a server administrator or a deterioration model developer.

The server 4 can establish a communication link with the network 2 via the communication interface 46 and further can simultaneously communicate with a plurality of information collection devices and a plurality of information reception devices via the network 2. The image processing unit 47 is a dedicated device that visualizes data collected from the information collection device as an image and includes a high-performance image processing processor.

A database 48a is constructed in the SSD/HDD 48. The database 48a processes, edits, and stores data collected from the plurality of information collection devices via the network 2. Since the data is obtained by collecting various kinds of data from various locations for a long period of time, the data can also be called big data. The stored data is delivered to the plurality of information reception devices. Data of the deterioration model itself constructed specifically for the reusable battery of each information collection device is also stored.

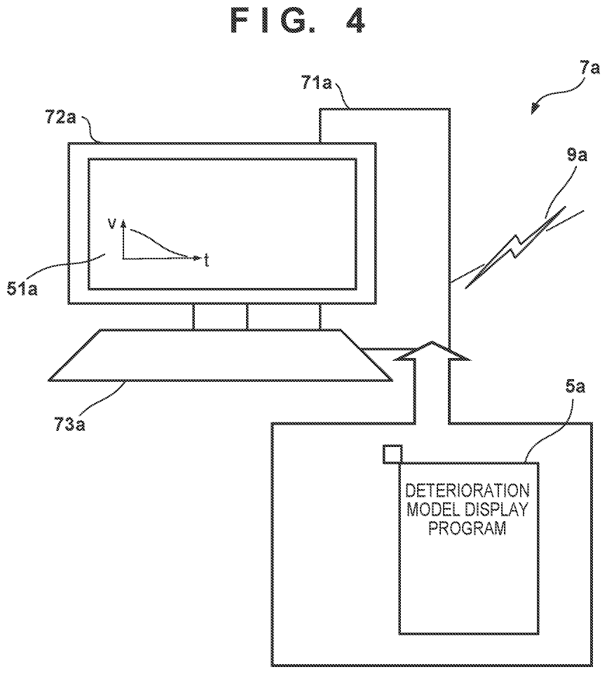

Since distribution of the delivered data and the reconstructed deterioration model itself are selective and paid according to the user's needs, a data delivery program that has a billing function is installed in the server 4. The CPU 42 executes the data delivery program to realize data delivery for a fee and provision of a deterioration model.

<Configuration of Information Reception Device (See FIG. 4)>

Here, a configuration of the information reception device 7a in a form of a personal computer (PC) which is a representative example of the information processing device will be described. A hardware configuration of the plurality of information processing devices differs depending on whether the information processing devices are PCs, tablet terminals, smartphones, or general-purpose computers. However, a basic configuration for realizing a function of receiving and displaying the delivered data is assumed to be the same, and thus only the PC form is taken as a representative example.

FIG. 4 is a diagram illustrating a schematic configuration of an information reception device in a PC form.

As illustrated in FIG. 4, the information reception device 7a in the form of a PC includes a main body 71a that contains a CPU, a memory, and an SSD/HDD, an LCD 72a, a keyboard 73a, and the like. A deterioration model display program is as an example of the application program 5a installed in the main body 71a.

When this deterioration model display program is executed by the CPU, the information reception device 7a establishes the communication link 9a with the server 4 via the network 2, receives data determined from the server 4, and displays the data on a screen 51a of the LCD 72. The received data is processed by the user who operates the information reception device 7a and is provided for use of the user.

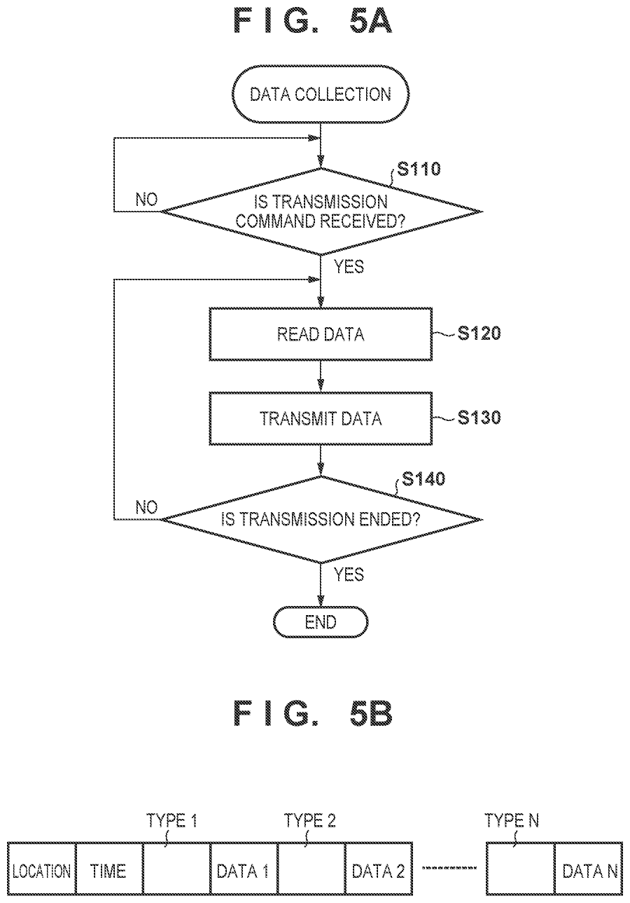

Next, a data collection and provision process performed by the information providing system that has the foregoing configuration will be described with reference to a flowchart.

<Description of Data Collection and Provision Process (See FIGS. 5A to 9)>1. Process of Information Collection Device (Reusable Battery) Side (See FIG. 5A)

FIG. 5A is a flowchart illustrating a data collection process performed by the reusable battery.

As illustrated in FIG. 5A, data collection is started in response to a transmission command from the server 4. When a predetermined time comes autonomously in the information collection device until the transmission command, the monitoring circuit (MONITOR) 64 acquires monitoring information of the battery cell 70 and stores the monitoring information in the memory 62. Further, detection information by the sensor group (SENSORS) 66 controlled by the sensor controller (CNTL) 65 is acquired and stored in the memory 62. Accordingly, at least the monitoring information and the detection information acquired after reception of a previous transmission command are stored in the memory 62 until reception of the transmission command. FIG. 5B illustrates a configuration of a transmission format of data transmitted from the reusable battery.

According to FIG. 5A, in step S110, reception of the transmission command from the server 4 is awaited. Then, when the transmission command is received, the process proceeds to step S120. Then, in step S120, data acquired by devices such as the monitoring circuit 64 and the sensor group 66 attached to the reusable battery and stored in the memory 62 is read. The data to be read is a temperature, an atmospheric pressure, a sunlight amount, an installation location, and the like from the sensor group 66. When the installation location is fixed, latitude and longitude data obtained from GPS data may be acquired only once. When the reusable battery is mounted on a mobile body, new latitude and longitude data is acquired at each data acquisition time. The discharge voltage, the output density, the cell temperature, the acceleration, and the like of the battery cell are obtained from the monitoring circuit 64.

Next, in step S130, the acquired data is transmitted by the communication unit (COMM) 63. A transmission data format at this time is as illustrated in FIG. 5B. That is, in FIG. 5B, a location indicates a data acquisition location, latitude and longitude data is based on GPS data, a time indicates a data acquisition time (YYMMDDhhmmss (year, month, day, minute, second)) by a sensor or a monitoring circuit, and a type indicates a data type. The data type is the temperature, the atmospheric pressure, the sunlight amount, the humidity, the discharge voltage of the battery cell, the output density, the cell temperature, and the like described above. According to this format, N pieces of data can be simultaneously transmitted. By using this format, it is possible to collect and transmit a plurality of pieces of data at a predetermined time.

Further, in step S140, it is determined whether the process ends. When it is determined that the process ends, the process ends. When it is determined that the process continues, the process returns to step S120 and data which has not been transmitted is read and transmitted. In addition, in the process illustrated in FIG. 5A, it is necessary to wait for a data transmission command from the server 4. Therefore, as long as the reusable battery normally operates, a state is a transmission command reception waiting state in step S110.

A type and a time range of data to be acquired are designated in the data transmission command, and data satisfying the designated condition is read from the memory 62.

Next, data collection, a deterioration model correction process, and a selling process performed by the server 4 will be described.

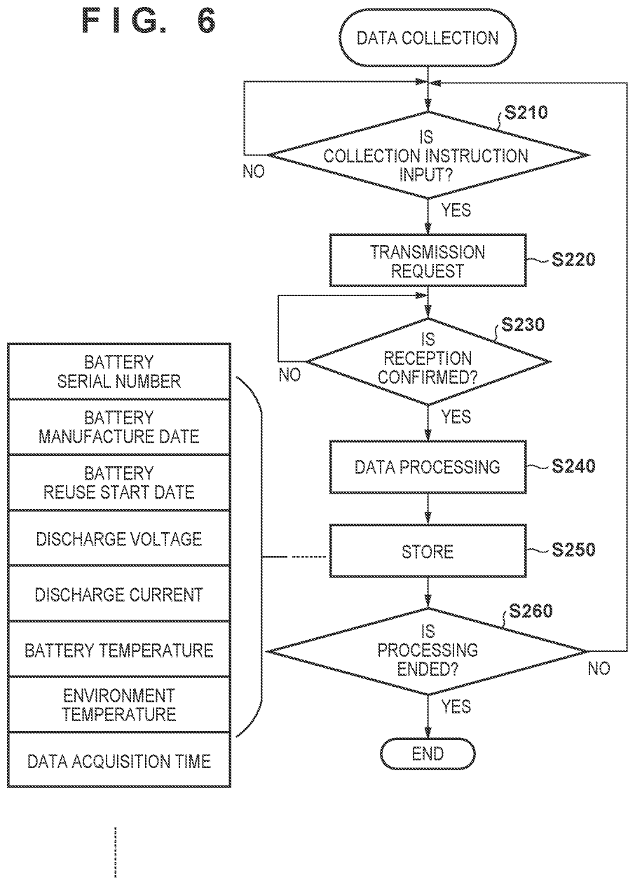

2. Process of Server Side (See FIGS. 6 to 9)

FIG. 6 is a flowchart illustrating details of the data collection process.

In step S210 of FIG. 6, data collection instruction input is first awaited. This instruction may be input from the terminal device 11 by a system operator or may be automatically issued when a predetermined time has come according to a timer set in the server 4. In any case, when there is a data collection instruction, the process proceeds to step S220, and a transmission instruction for a transmission request is issued to the information collection device. Then, in step S230, data reception in response to the transmission request is awaited, and the data reception is confirmed. The process of steps S210 to S230 is performed on the plurality of information collection devices, and data is collected from each of the plurality of information collection devices.

In step S240, the data collected from the plurality of information collection processes is processed in a data format according to a design of the database to store the data in the database 48a. Then, in step S250, the processed data is stored in the database 48a. The stored data includes, for each reusable battery, a battery serial number, a battery manufacture date, a battery reuse start date, a discharge voltage, a discharge current, a battery temperature, an environmental temperature, and a data acquisition time. Further, in step S260, it is determined whether the process ends.

When it is determined that the process ends, the process ends. However, when it is determined that the data collection from the desired information collection device does not end and the process continues, the process returns to step S210, and the data transmitted from the reusable battery is received.

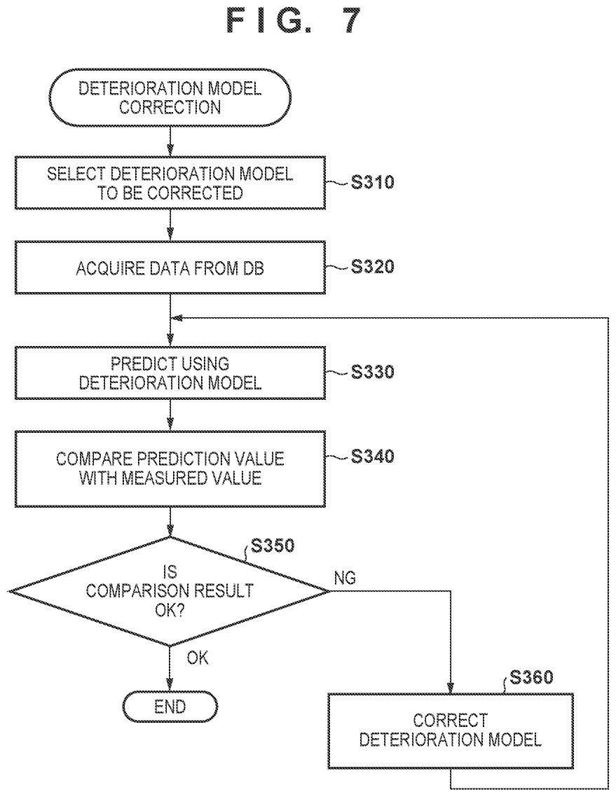

FIG. 7 is a flowchart illustrating the deterioration model correction process. Here, as illustrated in FIG. 4, the process performed in the server 4 will be described, but data may be transmitted from the server 4 to the terminal device 11 to be performed in the terminal device 11.

The deterioration model is usually generated to obtain a state of health (SOH) of a new secondary battery and is developed to predict the degree of deterioration in the secondary battery by testing a plurality of secondary batteries of the same standard. Therefore, the deterioration characteristics shown in the deterioration model are averaged for the plurality of secondary batteries of the same standard. However, a usage history of the reusable battery until reuse start differs for each battery, and a usage environment differs even after the reuse start. Therefore, the deterioration characteristics also differ from those included in the deterioration model on the premise of the new secondary battery.

The SOH indicating the deterioration characteristics can be formulated as a function f (x₁, x₂, . . . , xₙ) of various factors. Therefore, in the case of the reusable battery, more accurate deterioration prediction can be performed using the reevaluated deterioration characteristics based on the monitoring information obtained from each of the reusable batteries and sensor detection information than the deterioration characteristics averaged for the plurality of secondary batteries of the same standard. For this reason, the server 4 executes the process illustrated in FIG. 6 and corrects the deterioration model using the data collected for each reusable battery.

In step S310 of FIG. 7, a deterioration model to be corrected is selected. Next, in step S320, data of the reusable battery for predicting the degree of deterioration is acquired from the database 48a by using the deterioration model. Further, in step S330, deterioration prediction for a certain period is performed using the selected (pre-correction) deterioration model.

On the other hand, the SOH can be expressed using, for example, a temporal change in a discharge voltage of a target battery. Therefore, the discharge voltage of the target battery for the same period as a period in which the deterioration prediction is performed using the (pre-correction) deterioration model is acquired from the database 48a, and a temporal change (an actually measured value) is obtained. In step S340, the deterioration prediction is compared with the measured value using the (pre-correction) deterioration model. As a result, in step S350, when a difference between the two falls within a range of a predetermined threshold, it is determined that the continuously selected deterioration model is valid for the reusable battery targeted by the selected deterioration model and correction of the deterioration model is not necessary. Then, the process ends.

Conversely, when the difference between the two does not fall within the predetermined threshold range, the process proceeds to step S360. The deterioration model is corrected based on the actually measured value. This correction can be performed, for example, by obtaining a regression curve expressing a temporal change (an actually measured value) of the discharge voltage of the target reusable battery. Thereafter, the process returns to step S330 to repeat the above-described processes. When it is determined that a comparison result is good (OK), the process ends. The regression curve obtained in this way can be said to be an optimum deterioration model at least for the target reusable battery. The corrected deterioration model obtained by the foregoing process is stored in the SSD/HDD 48 in association with an applicable reusable battery.

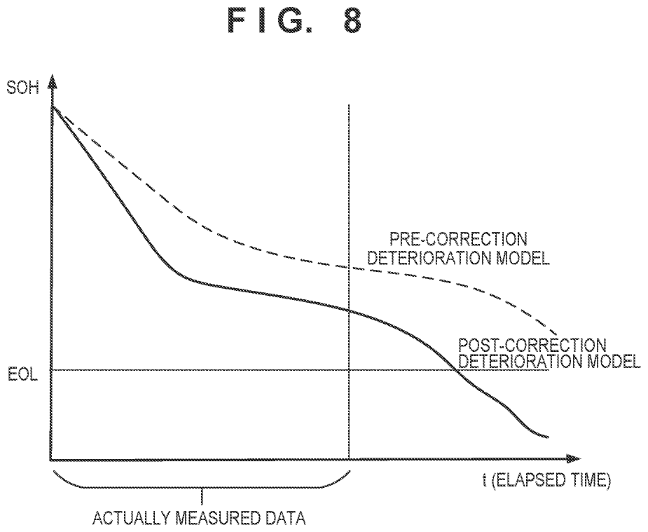

FIG. 8 is a diagram illustrating deterioration prediction by the pre-correction deterioration model and the post-correction deterioration model. In FIG. 8, the SOH can be predicted from a battery reuse start time point by using the pre-correction deterioration model. On the other hand, an actually measured data (for example, a temporal change of a discharge voltage) which can represent an SOH is stored in the database 48a from the battery reuse start time point to a time point indicated by a thin dotted line in the drawing. Therefore, reliability of the pre-correction deterioration model can be evaluated by comparing the actually measured data with a predicted value (a broken line) in accordance with the pre-correction deterioration model.

FIG. 8 is exemplary. When a regression curve obtained based on the actually measured data is adopted as a post-correction deterioration model, the degree of deterioration of the reusable battery can be more accurately predicted even in the future in which there is no actually measured data. By performing the data collection process and the deterioration model correction process as described above, the server 4 retains history data representing a state of each battery and an optimum deterioration model capable of predicting the degree of deterioration in each battery from each reusable battery.

Next, a process of selling the history data obtained by the above-described process and the deterioration model itself will be described.

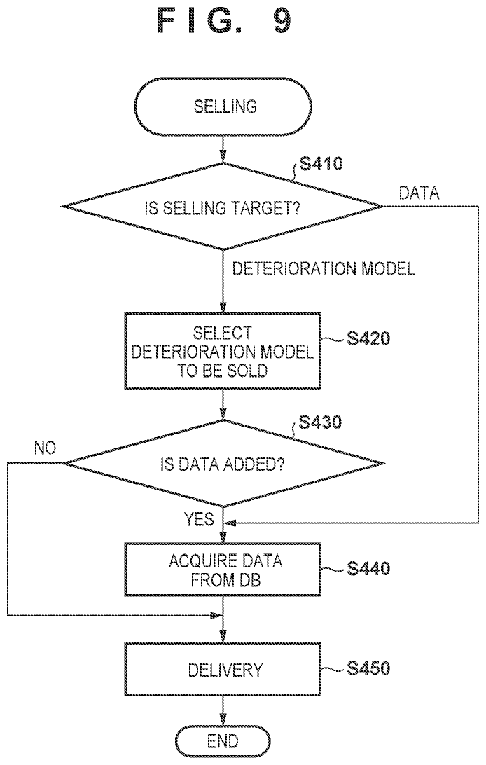

FIG. 9 is a flowchart illustrating a selling process executed by the server. Here, since the selling process will be described, it is assumed that a selling contract with the user is concluded. In addition, a selling target is the deterioration model itself, the collected data, or both the deterioration model and the collected data.

In step S410 of FIG. 9, it is examined whether the selling target is a deterioration model or data. Here, when the selling target is a deterioration model, the process proceeds to step S420, and the deterioration model to be sold is selected. Examples of the selling destination include an operator of the information collection device using a reusable battery to be predicted by the deterioration model. By using this deterioration model, it is possible to more accurately predict deterioration in the reusable battery used by the information collection device and perform optimum operation management.

Further, in step S430, it is determined whether to sell data in addition to the deterioration model. Here, when the data is sold together, the process proceeds to step S440. When the deterioration model itself is sold, the process proceeds to step S450. As a selling destination of both the deterioration model and the data, there is an operator of an information collection device using a reusable battery that has a standard or use history similar to that of the reusable battery to be predicted by the deterioration model. Thereafter, the process proceeds to step S450, and the data delivery process is performed.

In step S410, when the selling target is data, the process proceeds to step S440 and the above-described process is executed. Examples of a user who desires the data itself include a user who performs a power demand prediction and various predictions using the data acquired by the reusable battery.

Accordingly, according to the above-described embodiment, the information providing system can collect data acquired by the reusable battery from the plurality of information collection devices using the reusable battery, and deliver and provide the collected data to the user. Accordingly, it possible to effectively utilize the acquired data of the reusable batteries installed in various locations. In addition, a deterioration model intrinsic to each reusable battery can be constructed and the model itself can also be provided.

In the above-described embodiment, the example in which the deterioration model is corrected to a model intrinsic to each reusable battery and the model is sold has been described, but the present invention is not limited thereto. For example, when a reusable battery is used as a stationary power storage device for solar power generation, wind power generation, or the like, it is also possible to predict an electrical power demand for solar power generation or wind power generation by monitoring a temporal change in a discharge current from the reusable battery. On the other hand, since such solar power generation and wind power generation also have a specific use environment depending on an installation location, an operation environment of the reusable battery is also different. Therefore, it is also possible to construct a power demand model from the reusable battery based on monitoring information and sensor detection information obtained from the reusable battery. Further, from a business point of view, it can be determined that a selling price of the reusable battery is further lowered instead of collecting the history data for free from a user who purchases the reusable battery.

### CONCLUSION OF EMBODIMENTS

Configuration 1. An information providing system in which a plurality of information collection devices (3a, 3b, 3c, 3d), a server (4), and a plurality of information reception devices (7a, 7b, 7c, 7d) are connected by a network (2),

wherein each of the plurality of information collection devices includes:

a rechargeable battery (6a, 6b, 6c, 6d) that supplies power to drive the information collection device;

a monitoring circuit (64) that monitors a state of the battery;

a memory (62) that stores first data indicating a history of a state of the battery monitored by the monitoring circuit; and

a transmission unit (63) that transmits the first data stored in the memory via the network based on a request from the server,

wherein the server includes:

a request unit (46) that issues a data transmission request to each of the plurality of information collection devices via the network; and

a collection unit (46) that collects the first data from each of the plurality of information collection devices via the network; and

a database (48a) that stores the first data collected by the collection unit;

a construction unit (see FIG. 8) that constructs a model for predicting a future state of the battery based on the first data stored in the database; and

a providing unit (46) that provides at least one of the first data stored in the database and the model to the plurality of information reception devices via the network for a fee, and

wherein the plurality of information reception devices include:

a reception unit (71a) that receives at least one of the first data and the model provided from the server.

Configuration 2. The battery is a reusable battery (70) and includes a lithium ion battery.

Configuration 3. Each of the plurality of information collection devices further includes a sensor (66) that detects a state of an environment where the information collection device is installed,

the memory further stores second data indicating a state of the environment detected by the sensor, and

the transmission unit further transmits the second data, and

the collection unit further collects the second data.

Configuration 4. The first data indicating a history of a state of the battery monitored by the monitoring circuit includes a discharge voltage, a discharge current, a battery temperature, an acceleration, and a data acquisition time (see S250 in FIG. 6) of the reusable battery, and the second data includes a temperature, an atmospheric pressure, a sunshine time, and humidity.

Configuration 5. The construction unit corrects a first deterioration model for predicting a degree of deterioration in a new battery to a second deterioration model intrinsic to a reusable battery of the information collection device collecting the first data based on the first data (see FIG. 8).

Configuration 6. The construction unit compares the degree of deterioration predicted by using the first deterioration model with the degree of deterioration in the reusable battery based on the first data (S340) and corrects to the second deterioration model based on a result of the comparison (see S350) (see S360).

Configuration 7. The construction unit further constructs a power demand model in which the reusable battery is used, based on the first data and the second data.

Configuration 8. The network performs communication through wireless communication or wired communication.

Configuration 9. A server (4) that connects a plurality of information collection devices (3a, 3b, 3c, 3d) driven by power supplied from a rechargeable battery (6a, 6b, 6c, 6d) and a plurality of information reception devices (7a, 7b, 7c, 7d) via a network (2), the server (4) including:

a request unit (46) that issues a data transmission request to each of the plurality of information collection devices via the network;

a collection unit (46) that collects, via the network, data transmitted from each of the plurality of information collection devices in response to the transmission request;

a database (48a) that stores the data collected by the collection unit;

a construction unit (see FIG. 7) that constructs a model for predicting a future state of the battery based on the data stored in the database; and

a providing unit (46, see FIG. 9) that provides at least one of the data and the model stored in the database to the plurality of information reception devices for a fee via the network.

Configuration 10. An information providing method in a server (4) that connects a plurality of information collection devices (3a, 3b, 3c, 3d) driven by power supplied from a rechargeable battery (6a, 6b, 6c, 6d) and a plurality of information reception devices (7a, 7b, 7c, 7d) via a network (2), the method comprising:

a request step (see S210) of issuing a data transmission request to each of the plurality of information collection devices via the network;

a collection step (see S230) of collecting, via the network, data transmitted from each of the plurality of information collection devices in response to the transmission request;

a storing step of storing the data collected in the collection step in a database (48a);

a construction step (see FIG. 7) of constructing a model for predicting a future state of the battery based on the data stored in the database; and

a provision step (see FIG. 9) of providing at least one of the data and the model stored in the database to the plurality of information reception devices for a fee via the network.

According to Configurations 1 to 10 described above, it is possible to construct history data acquired by using a rechargeable battery and a specific model for predicting the state of the battery from the history data, and provide the history data and the specific model to various fields.

According to Configurations 1 to 10, it is possible to construct an accurate deterioration model based on the history data acquired by the rechargeable battery and use the deterioration model for the user.

According to Configurations 2 to 4, for example, it is possible to effectively use history data of a reusable battery such as a lithium ion battery and to effectively use data obtained from the reusable battery and data obtained in an installation environment of the reusable battery.

According to Configurations 5 to 7, it is possible to construct a deterioration model intrinsic to a reusable battery based on data obtained from each of the reusable batteries and conduct a business for providing the model itself or data for a fee. For example, a power demand model or the like can be constructed based on data obtained from each of the reusable batteries.

According to Configuration 8, since both wireless communication and wired communication can be used, data from an information collection device deployed in a remote area or an isolated area can be collected.

The invention is not limited to the foregoing embodiments, and various variations/changes are possible within the spirit of the invention.

What is claimed is:

1. An information providing system in which a plurality of information collection devices, a server, and a plurality of information reception devices are connected by a network,
each of the plurality of information collection devices comprising:
a rechargeable battery configured to supply power to drive the information collection device;
a monitoring circuit configured to monitor a state of the battery;
a sensor configured to detect a state of an environment where the plurality of information collection devices are installed;
a memory configured to store first data indicating a history of the state of the battery monitored by the monitoring circuit and second data indicating a state of the environment detected by the sensor; and
a transmission unit configured to transmit the first data and the second data stored in the memory via the network based on a request from the server,
the server comprising:
a request unit configured to issue a data transmission request to each of the plurality of information collection devices via the network;
a collection unit configured to collect the first data and the second data from each of the plurality of information collection devices via the network;
a database configured to store the first data and the second data collected by the collection unit;
a construction unit configured to construct a power demand model in which the battery is used based on the first data and the second data stored in the database; and
a providing unit configured to provide at least one of the first data and the second data stored in the database, and the power demand model to the plurality of information reception devices via the network for a fee, and
the plurality of information reception devices comprising:
a reception unit configured to receive at least one of the first data, the second data, and the power demand model provided from the server.

2. The information providing system according to claim 1, wherein the battery is a reusable battery and includes a lithium ion battery.

3. The information providing system according to claim 1, wherein the first data indicating the history of the state of the battery monitored by the monitoring circuit includes a discharge voltage, a discharge current, a battery temperature, an acceleration, and a data acquisition time of the reusable battery, and
the second data includes a temperature, an atmospheric pressure, a sunshine time, and humidity.

4. The information providing system according to claim 3, wherein the construction unit corrects a first deterioration model for predicting a degree of deterioration in a new battery to a second deterioration model intrinsic to a reusable battery of the information collection device collecting the first data based on the first data.

5. The information providing system according to claim 4, wherein the construction unit compares the degree of deterioration predicted using the first deterioration model with a degree of deterioration in the reusable battery based on the first data, and corrects the first deterioration model to the second deterioration model based on a result of the comparison.

6. The information providing system according to claim 1, wherein the network performs communication through wireless communication or wired communication.

7. A server that connects a plurality of information collection devices driven with power supplied from a rechargeable battery to a plurality of information reception devices via a network, the server comprising:
a request unit configured to issue a data transmission request to each of the plurality of information collection devices via the network;
a collection unit configured to collect, via the network, first data indicating a history of a state of the battery transmitted from each of the plurality of information collection devices and second data indicating a state of an environment where the plurality of information collection devices are installed in response to the transmission request;
a database configured to store the first data and the second data collected by the collection unit;
a construction unit configured to construct a power demand model in which the battery is used based on the first data and the second data stored in the database; and
a providing unit configured to provide at least one of the first data and the second data stored in the database, and the power demand model to the plurality of information reception devices via the network for a fee.

8. An information providing method in a server that connects a plurality of information collection devices driven by power supplied from a rechargeable battery and a plurality of information reception devices via a network, the information providing method comprising:
issuing a data transmission request to each of the plurality of information collection devices via the network;
collecting, via the network, first data indicating a history of a state of the battery transmitted from each of the plurality of information collection devices and second data indicating a state of an environment where the plurality of information collection devices are installed in response to the transmission request;
storing the collected first data and second data in a database;
constructing a power demand model in which the battery is used based on the first data and the second data stored in the database; and
providing at least one of the first data and the second data stored in the database, and the power demand model to the plurality of information reception devices via the network for a fee.
